(19) United States
(12) Patent Application Publication
(10) Pub. No.: US 2007/0171749 A1
(43) Pub. Date: Jul. 26, 2007

(54) DEVICE HAVING AN ARRAY OF NON-VOLATILE MEMORY CELLS AND A METHOD FOR ALTERING A STATE OF A NON-VOLATILE MEMORY CELL

(76) Inventor: Aviv Frommer, D. N. Misgav (IL)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/626,304

(22) Filed: Jan. 23, 2007

Related U.S. Application Data
(63) Continuation of application No. 60/762,130, filed on Jan. 26, 2006.

(51) Int. Cl. G11C 13/04; G11C 11/34; G11C 7/00

(52) U.S. Cl. 365/215; 365/114

(57) ABSTRACT

An array of non-volatile memory cells and a method for altering a state of a non-volatile memory cell that comprises multiple terminals, a substrate, and a charge retainer surrounded by an insulator, the method includes: illuminating the substrate with light such as to create electron-hole pairs within a first portion of the substrate positioned deep within the substrate and to create electron-hole pairs within a second portion of the substrate located near an upper surface of the substrate; and applying at least one control voltage to at least one terminal of the non-volatile memory cell such as to cause charged particles created in the first portion and in the second portion to propagate towards the upper surface of the substrate and to be injected into the charge retainer.

### RELATED APPLICATIONS

This application is a non-provisional of and claims priority to U.S. provisional patent Ser. No. 60/762,130, filing date Jan. 26, 2006 which is incorporated herein by reference.

### FIELD OF THE INVENTION

The invention is directed to devices that include non-volatile memory cells and to methods for altering a state of non-volatile memory cells.

### BACKGROUND OF THE INVENTION

Various types of non-volatile memory cells were developed during the last decades. They include read only memory (ROM) cells, programmable, erasable programmable, electrically erasable programmable and Flash electrically erasable programmable read only memory cells (PROM, EPROM, EEPROM and Flash EEPROM) and the like. For convenience, EPROMs, EEPROMs and flash EEPROMs are referred to collectively herein as programmable non-volatile memory.

A programmable non-volatile memory cell can be programmed to store a certain value, erased and than re-programmed. The different types of programmable non-volatile memory cells differ from each other by the manner in which they are erased (by ultraviolet radiation, by an electrical signal, in a serial manner, in parallel) as well as in the manner in which the non-volatile memory cells are connected to each other to form arrays of non-volatile memory cells (NAND formation, NOR formation, and other known array architectures).

Prior art non-volatile memory cells can include: (i) a floating gate that can store charge and alter the threshold voltage of the non-volatile memory cell between multiple values that reflect multiple digital values, (ii) a control gate, (iii) a body contact, (iv) a source, (v) a drain, and (vi) insulating layers that include an Inter-Gate Dielectric layer between the control gate and the floating gate and a gate dielectric layer between the floating gate and the substrate. The insulator surrounds the floating gate. The control gate, source, drain and body are connected to terminals. In other types of non-volatile memory cells the floating gate is replaced by a dielectric charge trapping layer.

The following articles, all being incorporated herein by reference, provide a brief illustration of some prior art non-volatile memory cells as well as method for programming and erasing non-volatile memory cells: Wegener, H. A. R, Lincoln, A. J., Pao, H. C., O'Connell, M. R., and Oleksiak, R. E. “Metal-insulator-semiconductor transistor as a non-volatile storage element”, International Electron Devices Meeting. 1967 (Abstracts) 58; Frohman-Bentchkowsky, D. “The metal-nitride-oxide-silicon (MNOS) transistor-characteristics and applications”, Proceedings of IEEE. 58, 1207 1970; Yatsuda, Y., Hagiwara, T., Kondo, R., Minami, S., and Itoh, Y. “N-channel Si-gate MNOS device for high speed EAROM. Proceedings 10^{th} Conference in Solid State Devices. Pg. 11 1979; Suzuki, E., Hiraishi, H., Ishi, K., and Hayashi, Y. “A low voltage alterable EEPROM with metal-oxide-nitride-oxide-semiconductor (MONOS) structure”. IEEE Transactions on Electron Devices, ED-30, pg. 122 1983; Eitan, B., Pavan, P., Bloom, I., Aloni, E., Frommer, A., Finzi, D. “NROM: A novel localized trapping, 2-bit nonvolatile memory cell”, IEEE Electron Device Letters, EDL-21, 543, 2000;

Two mechanisms were primarily used to program non-volatile memory cells. The first is known as tunneling (or FN tunneling) the second is based on hot carriers.

FN tunneling is illustrated in the following article, being incorporated herein by reference: Yeargain, J. and Kuo, K., “A high density floating gate EEPROM cell”, IEEE IEDM Technical Digest 1981, pg. 24.

In a nutshell, tunneling is based upon the passage of electrons through a thin (usually thinner than 12 nm) gate dielectric layer while maintaining a large control gate to body voltage (Vcb) and/or control gate to source voltage (Vcs) and/or control gate to drain voltage (Vdb) such as to form a strong electrical field across the gate dielectric layer (positioned between the floating gate and the substrate), that enables electrons to propagate (tunnel) from at least one region of the substrate to the floating gate, as illustrated by the following article, which is incorporated herein by reference: Lezlinger, M. and Snow, E. H. “Fowler-Nordheim tunneling in thermally grown SiO₂”. Journal of Applied Physics. 1978, No. 40, 278.

Several hot carrier mechanisms are known. These mechanisms are illustrated in the following article, being incorporated herein by reference: E. Takeda, Y. Nakagome, H. Kume, and S. Asai, “New hot-carrier injection and device degradation in submicron MOSFETs”, IEE PROC. Vol. 130 Pt. I No. 3, June 1983; some of these hot-carrier effects were suggested for programming non-volatile memory cells. The hot carrier method used in practically all EPROMs today is known as channel hot carrier injection. This mechanism is illustrated in the following articles, being incorporated herein by reference: Guterman, D., Rimawi, I., Chiu, T., Halvorson, R., and McElroy, D., “An electrically alterable nonvolatile memory cell using a floating gate structure”. IEEE Transactions on Electron Devices. 1979 ED-26, 576; J. D. Bude, A. Frommer, M. R. Pinto, and G. R. Weber, “EEPROM/flash sub-3.0 V drain-source bias hot carrier writing,” IEDM Tech. Dig., 1995, pp. 989-991;

Channel hot carrier injection, involves the injection of hot electrons (in the case of n-channel non volatile memory cell having a p-type body) to the floating gate. Hot channel electron injection involves applying a high positive control gate to source voltage (high Vcs) and applying a high drain to source voltage (Vds) such that electrons are accelerated along the channel such as to gain enough energy to surmount the energy barrier between the substrate and the gate dielectric.

Another hot carrier mechanism that was also proposed for programming non-volatile memory cells is substrate hot electron injection. This mechanism is illustrated in the following article, being incorporated herein by reference: Boaz Eitan, James L. Imccreary, Daniel Amrany, and Joseph Shappir, (1984) “Substrate Hot-Electron Injection EPROM”, IEEE Transactions on Electron Devices. ED-31, 934.

Substrate hot carrier injection involves the generation of excess carriers in the body of the device. When such carriers are present, a large channel to body potential drop accelerates this carriers towards the gate dielectric interface. Carriers gaining enough energy will surmount the energy barrier between the substrate and the gate dielectric.

Drain Avalanche Hot Carrier (DAHC) was also considered for injecting either electrons or holes. DAHC injection involves high drain to body bias. Avalanche multiplication due to impact ionization increases the supply of both hot electrons and hot holes. Thus both holes and electrons can surmount the energy barrier between the substrate and the gate dielectric.

Erasing the non-volatile memory cell can be done by Ultra-Violet (UV) radiation, FN tunneling or hot carrier injection. EPROMs are erased by UV radiation and are made with a transparent window that exposes the non-volatile memory cells to UV radiation emitted by dedicated UV erasers.

In the case of n-channel non volatile memory cell having a p-type body; tunneling erase based methods involve maintaining a large negative control gate to either body and/or source and/or drain voltage drop. Hot hole injection involves applying a sufficient potential to the drain-body or source-body junctions to cause avalanche hot carrier generation, a negative control gate to body voltage supports hot hole injection into the charge trapping region in contrast to electron injection.

Both tunneling and hot carrier injection programming and erasure involve applying relatively substantial electrical fields in order to generate high electric fields or high energy carriers. These processes wear out the thin insulating layer between the charge trapping region and the substrate, and are relatively time and energy consuming.

U.S. Pat. No. 3,950,738 of Hayashi et el. describes a non-volatile optical memory device that includes a light permeable charge retention means as well as a transparent electrode that enables light to directly illuminate onto the depletion region of a biased rectifying junction between a substrate and a drain of a device at the interface between the semiconductor and the insulator. Light propagates through the transparent electrode and the light preamble charge retention means hits the semiconductor-insulator interface and excites photo generated carriers. Photo-generated minority carriers (electrons in a p-type substrate) in the depletion region of the drain-body junction are accelerated by the junction bias. Electron injection is achieved when the junction is biased with a voltage that is higher than the electron barrier potential between the semiconductor and the insulating layer—φ_{b}, such as to supply enough energy to the photo-generated electrons to surmount the semiconductor to insulator potential barrier. Holes can also be injected into the charge retention means, by proper choice of the bias supplied to the optional auxiliary gate electrode. The device can be used to store light patterns. Such an injection mechanism requires a transparent charge retention layer and control gate electrode, and makes use only of those photons exciting electron-hole pairs at the semiconductor-insulator interface in the depletion region of the rectifying junction. It can thus make use only of those photons directly illuminating a small localized portion of the device and is thus extremely inefficient.

U.S. Pat. No. 4,665,503 of Glasser discloses a non-volatile memory cell that can be programmed by supplying bias voltage and illuminating by radiation that renders the insulator conductive, that is with photon energy higher than the sum of the substrate band-gap energy and the substrate to insulating gate-dielectric energy barrier (hν>E_{g}+φ_{b}). Only a certain portion of the cell is illuminated while preventing another portion of the cell from being illuminated. This selective illumination requires to design relatively large non-volatile memory cells and to tightly control the illumination of the non-volatile memory cell. In addition, in the case of a Si substrate and SiO2 gate dielectric hν>E_{g}+φb requires the use of UV radiation. UV radiation sources are relatively expensive, large and require high power.

There is a need to provide small size non-volatile memory cells and time and power efficient manners to program and erase non-volatile memory cells.

### SUMMARY OF THE INVENTION

A method for altering a state of a non-volatile memory cell that includes multiple terminals, a substrate, and a charge retainer surrounded by an insulator, the method includes: illuminating the substrate with light such as to create electron-hole pairs within a first portion of the substrate positioned deep within the substrate and to create electron-hole pairs within a second portion of the substrate located near an upper surface of the substrate; and applying at least one control voltage to at least one terminal of the non-volatile memory cell such as to cause electrons created in the first portion and in the second portion to propagate towards the upper surface of the substrate and to be injected into the charge retainer.

A device that includes a light source and non-volatile memory cells, wherein each non-volatile memory cell includes: multiple terminals, and a charge retainer surrounded by an insulator; wherein the light source is adapted to illuminate the substrate; wherein the substrate comprises a first portion positioned deep within the substrate and a second portion located near an upper surface of the substrate; and wherein the non-volatile cells are adapted, in response to the illumination of the substrate and in response to an appliance of at least one control voltage to at least one terminal out of the multiple terminals, to cause charged particles out of electron-hole pairs created in the first portion and in the second portion to propagate towards the upper surface of the substrate and to be injected into the charge retainer.

A device that includes: a first layer that includes light absorptive control lines adapted to provide control signals to multiple non-volatile memory cells; a second layer that includes light absorptive control lines adapted to provide control signals to multiple non-volatile memory cells; a third layer that includes multiple charge retainers that are surrounded by an insulator; wherein the third layer is placed below the first and second layers; and a light source; wherein each non-volatile memory cell further includes a substrate that comprises multiple semiconductor pn junctions defined between a body and other semiconductor regions of the non-volatile memory cell; wherein the substrate is placed below the third layer; wherein the device is adapted to alter its state by a propagation of photo-generated charged particles between the substrate and between the charge retainer; wherein the alteration of the state of the non-volatile memory cells is responsive to (i) a diffractive propagation of light through the first and second and possibly also the third layers towards the substrate and (ii) a provision of a control voltages to at least one light absorptive control line, wherein the diffractive propagation of light and the provision of at least one control voltage forces photo-generated charged particles to propagate between the substrate and between the charge retainer.

A method for altering a state of non-volatile memory cells, the method includes: illuminating, by diffractive illumination, a substrate of a non-volatile memory cell, wherein the illuminating comprises diffractive propagation of light through a first layer, a second layer and possibly also a third layer of a device, wherein the first layer comprises light absorptive control lines adapted to provide control signals to multiple non-volatile memory cells, the second layer comprises light absorptive control lines adapted to provide control signals to multiple non-volatile memory cells, the third layer comprises multiple charge retainers that are surrounded by an insulator; wherein the third layer is placed below the first and second layers; and a light source; wherein the substrate comprises multiple semiconductor pn junctions defined between a body and other semiconductor regions of the non-volatile memory cell; wherein the substrate is placed below the first, second and third layers; and providing at least one control voltage to at least one terminal of the non-volatile memory cell such as to alter a state of the non-volatile memory cell by propagation of photo-generated charged particles from the substrate to the charge retainer.

### BRIEF DESCRIPTION OF THE DRAWINGS

The present invention will be understood and appreciated more fully from the following detailed description taken in conjunction with the drawings in which:

FIGS. 1A and 1B illustrates two cross sectional views of a portion of a device according to an embodiment of the invention;

FIG. 2 illustrates a cross section of a portion of a non-volatile memory cell according to an embodiment of the invention;

FIG. 3 illustrates a cross section of a portion of a non-volatile memory cell according to an embodiment of the invention;

FIGS. 4 and 5 are energy band diagrams that illustrates programming of a floating gate memory cell by hot electron injection and by tunneling of photo-generated electrons according to various embodiments of the invention;

FIG. 6 is a cross sectional view of a device according to an embodiment of the invention;

FIG. 7 illustrates a relationship between the gate current and between the gate voltage of an n-channel MOS transistor, according to an embodiment of the invention; and

FIGS. 8-9 illustrate methods for affecting a state of a non-volatile memory cell, according to an embodiment of the invention.

### DETAILED DESCRIPTION OF THE INVENTION

Reference will now be made in detail to a specific embodiment of the invention. An example of this embodiment is illustrated in the accompanying drawings. While the invention will be described in conjunction with this specific embodiment, it will be understood that it is not intended to limit the invention to one embodiment. On the contrary, it is intended to cover alternatives, modifications, and equivalents as may be included within the spirit and scope of the invention. In particular, we describe in detail programming of n-channel, floating gate devices, with Silicon substrates and Silicon-Dioxide (SiO₂) gate dielectrics, by the method described by this invention. However, the programming and erasing methods of this invention are applicable for both floating gate and charge trapping memory cells. The invention applies also to p-channel devices and to devices using other types of semiconductor substrates and/or other types of gate dielectrics, and/or other types of charge trapping materials.

In the following description, numerous specific details are set forth in order to provide a thorough understanding of the present invention. The present invention may be practiced without some or all of these specific details. In other instances, well known methods and operations have not been described in detail in order not to unnecessarily obscure the present invention.

The methods and device of this invention speed up the programming (or erasure) processes by a combination of illumination and bias voltages that generate charged particles that can alter the state of a non-volatile memory cell by tunneling and/or by hot carrier injection.

By using illumination of the substrate layer by irradiation of the chip from the top and diffraction of the light off the various light absorptive layers above the semiconductor substrate, diffracted light hits the various regions of the semiconductor substrate. We call this method of illuminating the semiconductor substrate, diffractive illumination. Thus, when using diffractive illumination light absorptive conductors, semiconductor and dielectric layers can be used on top of the semiconductor substrate and the charge retention layer. It is noted that the term “light absorptive” also include opaque, highly absorptive and the like.

When illuminating the substrate by photons of certain energies and simultaneously applying voltages to the device terminals resulting in electric fields of certain amplitudes between the body and the semiconductor-insulator interface region of the memory cell and across a third intermediate insulating layer (formed between the charge retainer and the substrate), charged particles are caused to propagate between the semiconductor region and between a charge retainer that is surrounded by an insulator and change the logic state of the memory cell.

The use of illumination in addition to applying voltages to the memory cell terminals can increase the speed of alteration of the memory cell logic state (programming or easing), in addition it can reduce the required operating voltages. This reduction in program and/or erase time and/or in the operating voltages reduces also the wearing out of the non-volatile memory cell. Using diffractive illumination can prevent non-volatile memory cell re-design and does not require designing non-volatile memory cells in which parts of the substrate need to be exposed to direct illumination.

It may also be possible to speed the alteration of a state of a non-volatile memory cell by using illumination of the charge retainer and simultaneously applying voltages to the device terminals.

Conveniently, a method for altering a state of a non-volatile memory cell is provided. The non-volatile memory cell includes multiple terminals, a substrate, and a charge retainer surrounded by an insulator. The method includes: illuminating the substrate with light such as to create electron-hole pairs within a first region of the substrate positioned deep within the substrate and to create electron-hole pairs within a second region of the substrate located near an upper surface of the substrate; and applying at least one control voltage to at least one terminal of the non-volatile memory cell such as to cause electrons created in the first region and in the second region to propagate towards the upper surface of the substrate and to be injected into the charge retainer.

Conveniently, a device is provided. The device includes a non-volatile memory cell, wherein the non-volatile memory cell includes: a light source, multiple terminals, and a charge retainer surrounded by an insulator; wherein the light source is adapted to illuminate the substrate; wherein the substrate comprises a first region positioned deep within the substrate and a second region located near an upper surface of the substrate; and wherein the non-volatile cell is adapted, in response to the illumination of the substrate and in response to an appliance of at least one control voltage to at least one terminal out of the multiple terminals, to cause charged particles out of electron-hole pairs created in the first region and in the second region to propagate towards the upper surface of the substrate and to be injected into the charge retainer.

According to an embodiment of the invention a device is provided. The device includes: a first layer that includes light absorptive control lines adapted to provide control signals to multiple non-volatile memory cells; a second layer that includes light absorptive control lines adapted to provide control signals to multiple non-volatile memory cells; a third layer that includes multiple charge retainers that are surrounded by an insulator; wherein the third layer is placed below the first and second layers; and a light source; wherein each non-volatile memory cell further includes a substrate that comprises multiple semiconductor pn junctions defined between a body and other semiconductor regions of the non-volatile memory cell; wherein the substrate is placed below the third layer; wherein the device is adapted to alter its state by a propagation of photo-generated charged particles between the substrate and between the charge retainer; wherein the alteration of the state of the non-volatile memory cells is responsive to (i) a diffractive propagation of light through the first and second layers and possibly also through the third layer towards the substrate and (ii) a provision of a control voltages to at least one light absorptive control line, wherein the diffractive propagation of light and the provision of at least one control voltage forces photo-generated charged particles to propagate between the substrate and between the charge retainer.

According to an embodiment of the invention a method is provided. The method includes: illuminating, by diffractive illumination, a substrate of a non-volatile memory cell, wherein the illuminating comprises diffractive propagation of light through a first layer, a second layer and a third layer of a device, wherein the first layer comprises light absorptive control lines adapted to provide control signals to multiple non-volatile memory cells, the second layer comprises light absorptive control lines adapted to provide control signals to multiple non-volatile memory cells, the third layer comprises multiple charge retainers that are surrounded by an insulator; wherein the third layer is placed below the first and second layers; and a light source; wherein the substrate comprises multiple semiconductor pn junctions defined between a body and other semiconductor regions of the non-volatile memory cell; wherein the substrate is placed below the first, second and third layers; and providing at least one control voltage to at least one terminal of the non-volatile memory cell such as to alter a state of the non-volatile memory cell by propagation of photo-generated charged particles from the substrate to the charge retainer.

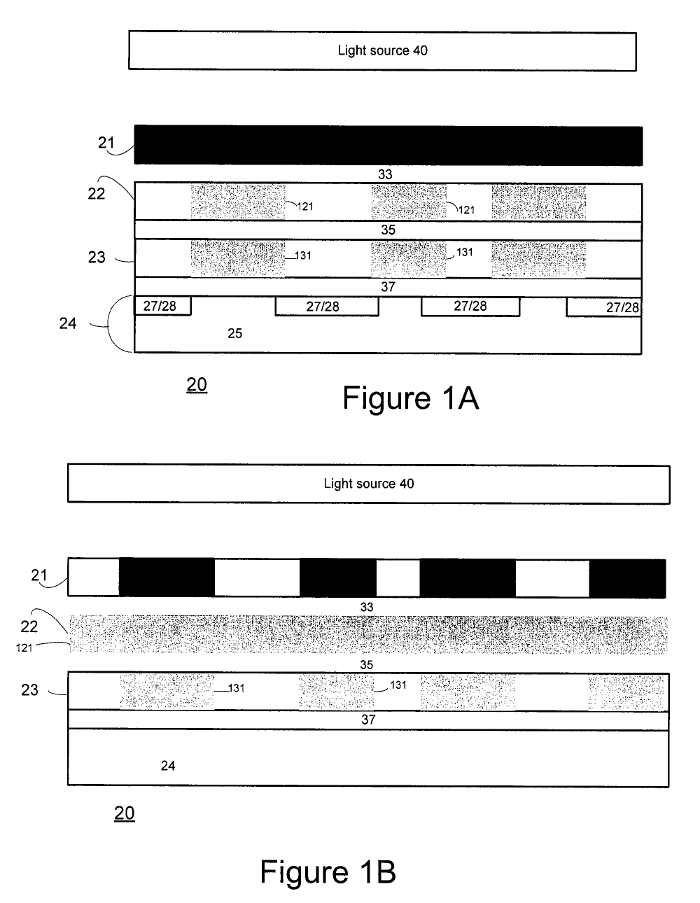

FIG. 1A illustrates device 20 according to an embodiment of the invention. FIG. 1B illustrates another cross section of device 20 according to an embodiment of the invention. It is noted that the cross-section of FIG. 1B should include insulator regions placed between adjacent non-volatile memory cells but for simplicity of explanation these insulator regions are not shown.

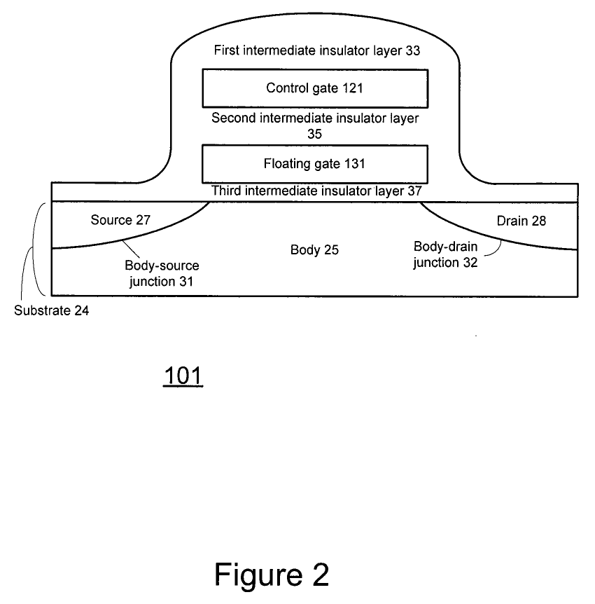

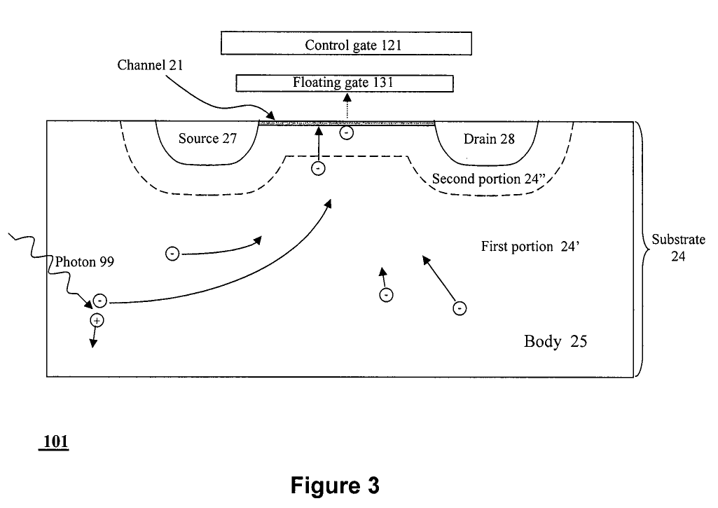

FIGS. 2 and 3 illustrates a portion of a non-volatile memory cell 101 according to an embodiment of the invention.

Device 20 includes multiple non-volatile memory cells such as non-volatile memory cell 101. Device 20 includes multiple layers such as but not limited first till third layers 21-23 as well as substrate 24 that includes body 25, sources 27 and drains 28 of the multiple non-volatile memory cells. Non-volatile memory cell 101 shows second layer that includes control gate 121 and third layer comprising floating gate 131, and semiconductor regions such as, substrate 24 containing body 25, source 27 and drain 28. Multiple semiconductor pn junctions (such as body-source junction 31 and body-drain junction 32) are formed in the semiconductor substrate 24.

First layer 21 includes light absorptive control lines adapted to provide control signals to the multiple non-volatile memory cells. First layer 21 is usually a metal layer and it includes metal conductors typically referred to as “bitlines” as well as transparent dielectric insulating material between the conductors. The metal conductors are opaque and their arrangement depends upon various factors including the manner in which the non-volatile memory cells are arranged.

Typically first layer 21 is placed below a transparent protective layer and some times additional opaque metallic layer or layers and additional inter-metal dielectric layers.

The Non-volatile memory cell 101 terminals include: control gate 121, body 25, source 27 and drain 28 can be connected to conductors for receiving control voltages. These terminals can be directly or indirectly (via other non-volatile memory cells) be connected to the external device terminals depending upon the arrangement (for example NAND, NOR, etc.) of a non-volatile memory array that includes multiple non-volatile memory cells 101.

Second layer 22 of device 20 includes light absorptive regions adapted to deliver control signals. Second layer 22 can include multiple control gate conductors typically referred to as “word lines”.

Third layer 23 of device 20 includes multiple charge retainers that are surrounded by insulator.

Non-volatile memory cell 101 includes floating gate 131 that is surrounded by insulating materials and is not connected to any of the terminals of the non-volatile memory cell 101.

Conveniently, first intermediate insulating layer 33 is formed between the first and second layers 21 and 22, second intermediate insulating layer 35 is formed between the second and third layers 22 and 23, and third intermediate insulating layer 37 is formed between the third layer 23 and the substrate 24. Non-volatile memory cell 101 includes first to third intermediate insulator layers 33-37. Layer 33 is formed above control gate 121, layer 35 is formed between control gate 121 and between floating gate 131, and third intermediate insulating layer 37 is formed between floating gate 131 and between substrate 24.

It is noted that the light absorptive control lines of first layer 21 and of second layer 22 form each a diffraction grating though which light of proper wavelength can be diffracted through. In the case of floating gate devices layer 23 is also absorptive, and it too forms a diffraction grating though which light can be diffracted through. The diffraction gratings are formed as the width of the lines and the spacing between lines are typically on the order of, or smaller than the wavelength of the light that is used to illuminate device 20.

In many cases the light does not directly impinge on most regions of the substrate but rather propagates towards most regions of the substrate only by diffraction. Thus, there is no need to design the device such that light will directly illuminate certain regions of the substrate. In addition, the conductors as well as the control gates and the charge retainer layers do not need to be transparent.

Accordingly, the light is diffracted off these diffraction gratings, and spreads also to the regions underneath these layers. It is also possible to design the relationship between the pitch, the line-width and the spacing of these grating patterns of the non-volatile memory array in order to receive required illumination efficiency. Additionally or alternatively, the wavelength of the light can be selected to provide optimal illumination efficiency per given memory array structure.

It is noted that the light can be provided from a monochromatic light source, non-monochromatic light source and even a broadband light source.

Each charge retainer within third layer 23 is adapted to change a state of its non-volatile memory cell by propagation of charged particles between the substrate and between the charge retainer. Charged particles are generated in response to a diffractive propagation of light through first, second and possibly third layers 21, 22 and 23 towards the substrate. The charged particles are forced to propagate between the substrate and between the charge retainer by a provision of control voltages to at least some of the memory cell terminals.

Each charge retainer within third layer 23 can be adapted to retain the state of its non-volatile memory cell even when charged particles are photo-generated in the charge retainer layer and/or in the substrate by provision of a control voltage to at least some of the memory cell terminals that inhibit the propagation of charge particles between the substrate and the charge retainer.

Device 20 includes multiple memory cells. Thus, the non-volatile memory cells of device 20 can be arranged in a NAND format (as shown in FIG. 1) or in an NOR format or in other known non-volatile memory array architectures.

Device 20 also includes a light source 40. Light source 40 can include one or more small light sources that are integrated within device 20. For example, the inventor used a light emitting diode (LED), although other light sources such as an LED array a laser or laser arrays can be used. Light source 40 is illustrated in FIG. 1 as being placed above and substantially parallel to the multiple non-volatile memory cells, although this is not necessarily so. According to an embodiment of the invention the intensity of the light source can be controlled by one or more control signals. The initial intensity can be set according to the logic state to be programmed to the memory cells, and can be varied according to the process being implemented (programming or erasure), as well as in response to the progress of that process (start of programming or erasure, reception of feedback reflecting the state of the program or erasure process and the like).

According to another embodiment of the invention the light source can use reflective or non-normal incidence illumination.

Conveniently, the non-volatile memory cells are arranged in groups. Typically, program/erasure includes illuminating multiple groups while programming/erasing only some of the memory cells in some (even just one) of the groups. This can involve providing programming/erasure compliant bias to the selected non-volatile memory cells of a selected group and providing programming/erasure inhibit compliant bias to the rest of the (deselected) non-volatile memory cells of the selected group and to the memory cells of the other (deselected) groups.

Those of skill in the art will appreciate that various relationships between the number and size of illumination elements and between the number of non-volatile memory cells in each group can exist. For example, there can be one light source per sector, per multiple sectors, per a fraction of a sector and the like.

Conveniently, the wavelength of the light is chosen such that the photon energy is higher than the band-gap energy (Eg) of the semiconductor substrate hν>Eg. For example Eg is about 1.1 electron-volts for Silicon. When a photon having energy of hν is absorbed by the substrate it generates an electron-hole pair and the excited electron has an excess energy (Ee) that is smaller than or equal to the difference between the photon energy and the band-gap energy. In mathematical terms Ee≦hν−Eg.

According to an embodiment of the invention the photon energy is further chosen such that the maximal excess electron energy will not exceed the semiconductor to gate dielectric energy barrier for electrons—φ_{b}. For a Si—SiO₂ interface this barrier is about 3.2 electron volts.

In mathematical terms: E_{g}+φ_{b}>hν≧Eg, or: 0≦Ee<φ_{b}

Non-volatile memory cell 101 includes a silicon p-type body 25, n-type source 27, n-type drain 28 formed in substrate 24. Substrate 24 includes a first portion 24′ and a second portion 24″. First portion 24′ is positioned deep within substrate 24 and second portion 24″ is positioned near the upper surface of substrate. Conveniently, second portion is the depletion region that partially surrounds source 27, drain 28 and channel 21 that is formed at the upper surface of substrate. Non-volatile memory cell 101 also includes a third insulator layer positioned between substrate 24 and floating gate 131.

First portion 24′ can include most of substrate 24, although it may include smaller regions of substrate 24. Second portion 24″ can include, for example, the upper surface of substrate 24, source 27, drain 28 and the like. FIG. 3 illustrates second portion 24″ as being the depletion region but this is not necessarily so. Second portion 24″ can include at least a substantial portion of a depletion region.

Conveniently, source 27 and drain 28 are connected to each other, a zero or positive source/drain to body voltage and a positive control-gate to body voltage (Vcb) are applied. The applied voltages generate an inversion layer (channel) under the floating gate surrounded by a depletion region. There is a potential drop between the body and the channel region of the memory cell and across the gate oxide insulator. Photo-generated electrons in the substrate region surrounding the memory cell diffuse towards the depletion region. As they enter the depletion region and drift towards the Si—SiO₂ interface they gain energy from the electric field in the depletion region. Some of the photo-generated electrons are collected by the source and drain, others are injected into the charge retainer and contribute to programming of the memory cell as hot carriers or by tunneling according to an embodiment of the present invention. If no other sinks are available for the photo-generated substrate electrons, the memory cell that is biased for programming can attract these electrons from large distances across the chip. In a memory array environment, collection of the photo-generated electrons by source and/or drain junctions can be inhibited by floating the source and/or drain terminals. In some array arrangements floating the source and/or drain of the memory cell that is being programmed itself may be possible, in others it can be done only to the memory cells neighboring the memory cell that is being programmed.

It should be noted that when the field across the depletion region is strong enough, multiplication through impact-ionization is also possible. Secondary electrons generated through impact ionization will also drift towards the Si—SiO₂ interface, and can also contribute to electron injection towards the charge retainer either as hot electrons surmounting the interface energy barrier or by tunneling. Thus one photon may in principle contribute to injection of multiple electrons into the charge retainer.

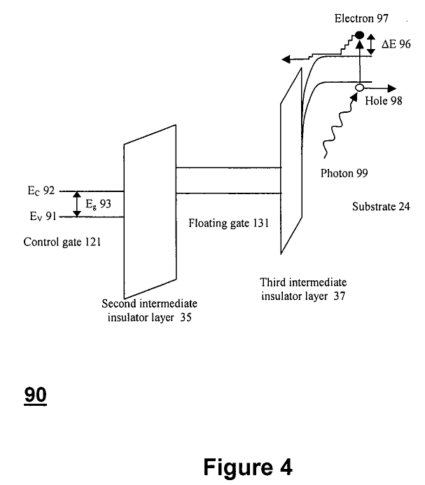

FIG. 4 is an energy band diagram 90 that illustrates hot electron injection of photo-generated electrons in the semiconductor substrate towards the floating gate according to an embodiment of the invention.

It shows those electrons arriving at the interface with energy greater than the interface energy barrier that are emitted towards the floating gate as hot electrons.

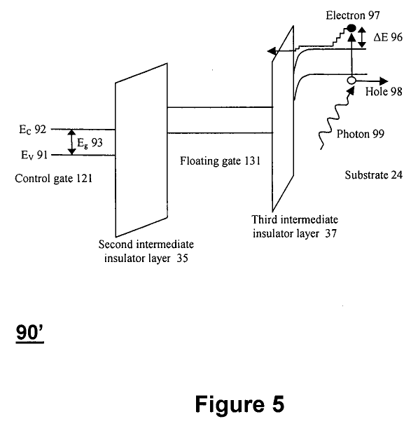

FIG. 5 is an energy band diagram 90′ that illustrates tunneling of photo-generated electrons in the semiconductor substrate towards the floating gate according to an embodiment of the invention. It shows that even those electrons arriving at the interface with energy below the barrier could also be emitted towards the floating gate by tunneling.

In FIGS. 4 and 5 E_{C} 92 is the conduction band edge, E_{V} 91 is the valance band edge, E_{g} 93 is the energy band gap (Eg=Ec−Ev).

Photon 99 hits substrate 24 and causes a pair of electron 97 and hole 98 to be formed. The energy of the electron is increased by ΔE 96 above the bottom of the conduction band. The photo-generated electrons quickly lose their excess energy to phonons as they flow towards the semiconductor-insulator interface. When they reach the channel depletion region they gain excess energy from the depletion region electric field. Those electrons arriving at the semiconductor-insulator interface with energy greater than the interface barrier height are emitted towards the floating gate as hot electrons (as illustrated in FIG. 4). Those arriving with energy below the barrier could be emitted towards the floating gate by tunneling (as illustrated in FIG. 5). This process is used during programming non-volatile memory cells according to one embodiment of this invention.

In the case of tunneling high energy photo-generated electrons have a much higher probability to tunnel through the gate dielectric towards the floating gate compared to the channel electrons due to their excess energy and the reduced energy barrier to tunnel through. The electron excess energy can be both from their initial excess energy after their photo-generation that was not lost to phonons and due to the excess energy gained from the depletion region electric field. In the case of hot electron injection (FIG. 4), photo-generated electrons generated deep in the substrate, are accelerated towards the Si—SiO₂ interface in the depletion region gaining additional excess energy. The conditions for efficient photo-induced hot electron injection is that the total energy of enough of the electrons photo-generated in the body together with their excess energy due to the body to channel potential drop minus the energy lost on the way (primarily to phonons) is higher than the Si—SiO₂ energy barrier.

By controlling the source, drain, body and control gate potentials of the memory cell, the semiconductor-insulator interface potential and the field across the insulator are also set, and programming by either tunneling and/or hot electrons of photo-generated electrons can be induced or inhibited.

Accordingly, by photo-generating enough electrons, the programming time of a non-volatile memory cell can be reduced. In addition, since the period during which the third insulator intermediate layer is under high electric field stress is reduced, the wear-out of that layer is reduced and the endurance (number of programming/erase cycles) of the non-volatile memory cell is expected to increase.

Additionally, by using high energy photo-excited electrons to charge the floating gate lower voltages can be used for the programming of the non-volatile memory cell. Use of lower voltages also reduces the electric field stress on the third insulator intermediate layer.

By using lower voltage levels the memory array circuitry can be simplified and even sized-reduced as high voltage transistors may not be required.

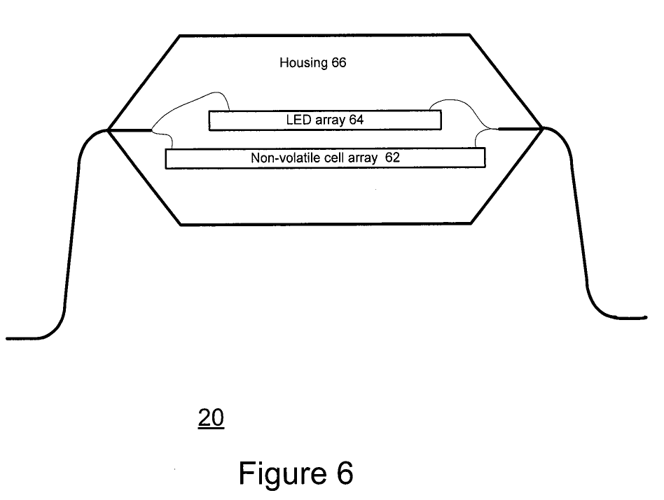

FIG. 6 illustrates a cross section of an exemplary packaged device 20 according to an embodiment of the invention.

Device 20 includes a non-volatile memory array chip 62 that is positioned in parallel to and below a light emitting diode array 64. Both arrays can be fabricated independently but both arrays are placed within a single housing 66. Device 20 can include multiple pins through which data, address and control signals (including LED array 64 control signals) can be applied. The state of the non-volatile memory array 62 can also be sensed by using various pins.

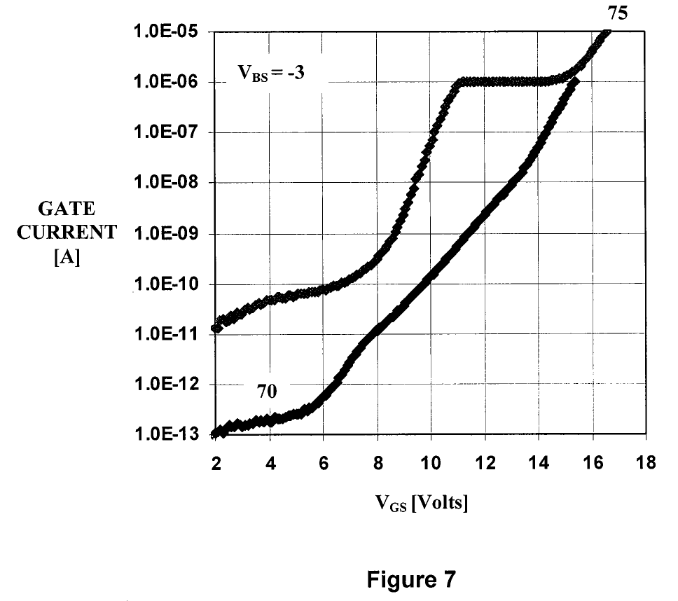

FIG. 7 illustrates the relationship between the gate current and the gate to source/drain (source and drain are tied together) voltage (V_{GS}) of an n-channel MOSFET with a multi-finger gate structure. The total gate area was 495[μm²] and the device had a 10 nm thick SiO₂ gate dielectric. Gate current (I_{G}) was measured with grounded source and drain and a body to source potential of V_{BS}=−3V.

The gate current represents the propagation of electrons from the substrate to the gate. This current is a measure of the current charging a floating gate in a non-volatile floating gate memory cell.

Curve 70 illustrates the gate current without illumination while curve 75 illustrates the gate current while illuminating the device with light having a central wavelength of 470 nm.

Curve 70 shows a typical FN tunneling gate current characteristic.

Curve 75 illustrates that with illumination the gate current increases substantially over the entire gate voltage range. It has a substrate hot electron like gate current characteristic for voltages up to ˜8V and a characteristic that resembles a FN tunneling like gate current characteristic for voltages above 8V. For V_{G}>10.8V, I_{G} remains at substantially the same level, even if the gate voltage further increases. The level at which the leveling of the gate current occurs depends on the light intensity. Its value was used to calculate the efficiency of photo-generated electron injection which was shown to be as high as 10⁻¹ for this device. The electron collection was from the entire illuminated chip area. Curve 75 illustrates that for high gate voltages the gate current will remain substantially the same regardless of various possible process variations, depending only on the light intensity, indicating that light intensity can be used as an efficient knob to control electron injection rate in a non-volatile memory cell.

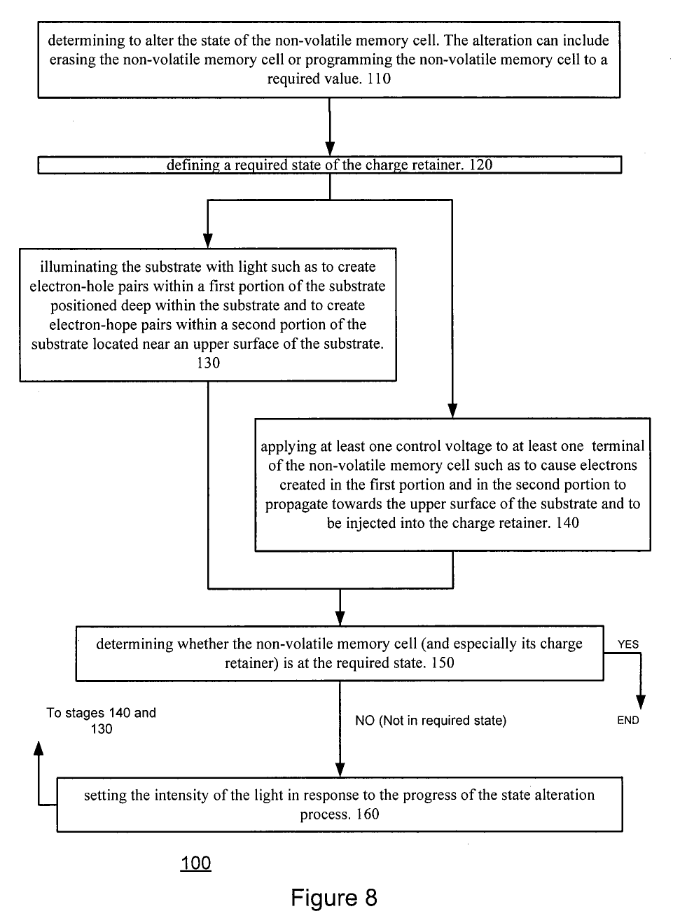

FIG. 8 illustrates method 100 for altering a state of a non-volatile memory cell, according to an embodiment of the invention.

Method 100 starts by stage 110 of determining to alter the state of the non-volatile memory cell. The alteration can include programming the non-volatile memory cell or erasing the non-volatile memory cell to a required logic state.

Stage 110 is followed by stage 120 of defining a required state of the non-volatile memory cell. The non-volatile memory cell should be at that required state after the state alteration process is completed. This state reflects the charge that is retained by the charge retainer of the non-volatile memory cell. Stage 120 may include setting the intensity of the light according to the logic state to be programmed.

Stage 120 is followed by stages 130 and 140. Stage 130 includes illuminating the substrate with light such as to create electron-hole pairs within a first portion of the substrate positioned deep within the substrate and to create electron-hope pairs within a second portion of the substrate located near an upper surface of the substrate.

Stage 140 includes applying at least one control voltage to at least one terminal of the non-volatile memory cell such as to cause electrons created in the first portion and in the second portion to propagate towards the upper surface of the substrate and to be injected into the charge retainer.

Stage 140 can be followed by stage 150 of determining whether the non-volatile memory cell is at the required logic state. If the answer is positive method 100 ends. FIG. 8 illustrates stage 150 as being followed by optional stage 160 (if the answer is negative). If stage 160 is not applied (and the answer is negative) then stage 150 can be followed by stages 130 and 140.

Conveniently, stage 150 is followed by stage 160 of setting the intensity of the light in response to the progress of the state alteration process. Thus, the intensity of the light source can be varied between iterations of stage 130.

It is noted that although stages 110-160 were illustrated in reference to a single non-volatile memory cell that multiple memory cells can be programmed or erased concurrently. For example, method 100 can include illuminating a first and second group of non-volatile memory cells, altering a state of a first group of non-volatile memory cells while preventing non-volatile memory cells of the second group from altering their state.

According to an embodiment of the invention stage 140 includes maintaining a first potential drop between an upper surface of the substrate and between other parts of the substrate and maintaining a second potential drop between an upper portion of the substrate and the charge retainer.

Conveniently, stages 130 and 140 of applying and illuminating cause charged particles of the electron-hole pairs to tunnel through a third insulator region positioned between the substrate and between the charge retainer.

Conveniently, stages 130 and 140 of applying and illuminating cause charged particles of the electron-hole pairs to accelerate towards an upper surface of the substrate and surmount a potential barrier between the upper surface of the substrate and between a third insulator layer positioned between the upper surface of the substrate and between the charge retainer.

Conveniently, stages 130 and 140 of applying and illuminating cause charged particles of the electron-hole pairs to surmount a potential barrier between the upper surface of the substrate and between a third insulator layer positioned between the upper surface of the substrate and between the charge retainer and to cause multiple charged particles of the electron-hole pairs to tunnel through the third insulator region.

Conveniently, stage 130 includes illuminating the non-volatile memory cell with photons that have photon energy that is higher than the band-gap energy of the substrate.

Conveniently, stage 130 includes illuminating the non-volatile memory cell with photons that have photon energy that is smaller than a sum of the band-gap energy of the substrate and the potential barrier between the substrate and between a third insulator layer positioned between the substrate and between the charge retainer.

Conveniently, stage 130 includes illuminating the non-volatile memory cell with photons that have photon energy that is higher than the band-gap energy of the substrate and is smaller than a sum of the band-gap energy of the substrate and a potential barrier between the substrate and between a third insulator layer positioned between the substrate and between the charge retainer.

Conveniently, method 100 includes defining a required state (in terms of logic level) of the non-volatile memory cell and selectively repeating the stages of illuminating and applying until the memory cell is at the required state.

Conveniently, method 100 includes defining a required state (in terms of logic level) of the non-volatile memory cell and setting an initial intensity of the light according to the required state.

Conveniently, method 100 includes altering an intensity of the light between two iterations of the illuminating.

Conveniently, method 100 includes illuminating a first non-volatile memory cell and a second non-volatile memory cell that is adjacent to the first memory cell and wherein the method further comprises applying at least one control voltage to at least one terminal of the second non-volatile memory cell such as to substantially prevent charged particles created in the substrate to be injected into a charge retainer of the second non-volatile memory cell.

Conveniently, method 100 includes illuminating a first and second group of non-volatile memory cells, altering a state of a first group of non-volatile memory cells while preventing non-volatile memory cells of the second group from altering their state.

Conveniently, method 100 includes illuminating a non-volatile memory cell in which the charge retainer is a floating gate.

Conveniently, method 100 includes illuminating a non-volatile memory cell in which the charge retainer is a charge trapping region.

Conveniently, stage 130 includes illuminating the substrate by diffractive illumination.

Conveniently, stage 130 includes directing at least one light beam towards multiple light absorptive portions of multiple non-volatile memory cells positioned above multiple semiconductor regions of the multiple non-volatile memory cells.

Conveniently, stage 130 includes illuminating the non-volatile memory cells by a light source positioned substantially above the non-volatile memory cell and positioned substantially in parallel to the non-volatile memory cell.

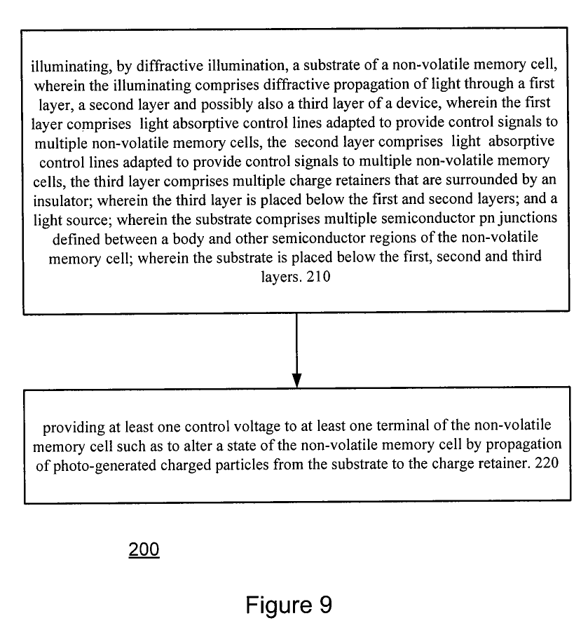

FIG. 9 illustrates method 200 for altering a state of a non-volatile memory cell, according to an embodiment of the invention.

Method 200 starts by stage 210.

Stage 210 includes illuminating, by diffractive illumination, a substrate of a non-volatile memory cell, wherein the illuminating comprises diffractive propagation of light through a first layer, a second layer and possibly also a third layer of a device, wherein the first layer comprises light absorptive control lines adapted to provide control signals to multiple non-volatile memory cells, the second layer comprises light absorptive control lines adapted to provide control signals to multiple non-volatile memory cells, the third layer comprises multiple charge retainers that are surrounded by an insulator; wherein the third layer is placed below the first and second layers; and a light source; wherein the substrate comprises multiple semiconductor pn junctions defined between a body and other semiconductor regions of the non-volatile memory cell; wherein the substrate is placed below the first, second and third layers.

Stage 220 includes providing at least one control voltage to at least one terminal of the non-volatile memory cell such as to alter a state of the non-volatile memory cell by propagation of photo-generated charged particles from the substrate to the charge retainer.

It is noted that although stages 210-220 were illustrated in reference to a single non-volatile memory cell that multiple memory cells can be programmed or erased concurrently. For example, method 200 can include illuminating a first and second group of non-volatile memory cells, altering a state of a first group of non-volatile memory cells while preventing non-volatile memory cells of the second group from altering their state.

Conveniently, method 200 includes at least one of the following: (i) maintaining a reverse bias across at least one semiconductor pn junction within the substrate; (ii) maintaining at least one semiconductor region out of a pair of semiconductor regions that form a semiconductor pn floating; (iii) illuminating multiple non-volatile memory cells that are arranged in a NAND format; or (iv) illuminating multiple non-volatile memory cells that are arranged in a NOR format.

Conveniently, the stages of illuminating and providing cause photo-generated charged particles to tunnel through an insulator positioned between the substrate and between the charge retainers.

Conveniently, the stage of illuminating and providing cause photo-generated charged particles to accelerate towards the upper surface of the substrate and surmount a potential barrier between the substrate and between an insulator positioned between the upper surface of the substrate and between the charge retainer.

Conveniently, the stages of illuminating and providing cause photo-generated charged particles to surmount a potential barrier between the substrate and between an insulator positioned between the upper surface of the substrate and between the charge retainers and to cause multiple photo-generated charged particles to tunnel through the insulator.

Conveniently, the stage of illuminating includes illuminating the non-volatile memory cell with photons that have photon energy that is higher than a band-gap energy of the substrate.

Conveniently, the stage of illuminating includes illuminating the non-volatile memory cell with photons that have photon energy that is smaller than a sum of the band-gap energy of the substrate and the potential barrier between the substrate and between an insulator positioned between the substrate and between the charge retainers.

Conveniently, the stage of illuminating includes illuminating the non-volatile memory cell with photons that have photon energy that is higher than a band-gap energy of the substrate and is smaller than a sum of the band-gap energy of the substrate and a potential barrier between the substrate and between an insulator positioned between the substrate and between the charge retainers.

Conveniently, method 200 includes defining a required state of a non-volatile memory cell and selectively repeating the stages of illuminating and providing until the non-volatile memory cell is at the required state.

Conveniently, method 200 includes defining a required state of a non volatile memory cell and setting an initial intensity of the light according to the required state.

Conveniently, method 200 includes altering an intensity of the light between two iterations of the illuminating.

Conveniently, method 200 includes illuminating a first non-volatile memory cell and a second non-volatile memory cell that is adjacent to the first memory cell and method further comprises applying at least one control voltage to at least one terminal of the second non-volatile memory cell such as to substantially prevent photo-generated charged particles created in the substrate to be injected into a charge retainer of the second non-volatile memory cell.

Conveniently, method 200 includes illuminating a first and second group of non-volatile memory cells, altering a state of a first group of non-volatile memory cells while preventing non-volatile memory cells of the second group from altering their state.

Although the invention has been described in conjunction with specific embodiments thereof, it is evident that many alternatives, modifications and variations will be apparent to those skilled in the art, accordingly, it is intended to embrace all such alternatives, modifications and variations that fall within the spirit and broad scope of the appended claims.

What is claimed is:

1. A method for altering a state of a non-volatile memory cell that comprises multiple terminals, a substrate, and a charge retainer surrounded by an insulator, the method comprises:
illuminating the substrate with light such as to create electron-hole pairs within a first portion of the substrate positioned deep within the substrate and to create electron-hope pairs within a second portion of the substrate located near an upper surface of the substrate; and
applying at least one control voltage to at least one terminal of the non-volatile memory cell such as to cause electrons created in the first portion and in the second portion to propagate towards the upper surface of the substrate and to be injected into the charge retainer.

2. The method according to claim 1 wherein the applying comprises maintaining a first potential drop between an upper surface of the substrate and between other parts of the substrate and maintaining a second potential drop between the upper portion of the substrate and the charge retainer.

3. The method according to claim 1 wherein the applying and illuminating cause charged particles of the electron-hole pairs to tunnel through a third insulator region positioned between the substrate and between the charge retainer.

4. The method according to claim 1 wherein the applying and illuminating cause charged particles of the electron-hole pairs to accelerate towards the upper surface of the substrate and surmount a potential barrier between the upper surface of the substrate and between a third insulator layer positioned between the upper surface of the substrate and between the charge retainer.

5. The method according to claim 1 wherein the applying and illuminating cause charged particles of the electron-hole pairs to surmount a potential barrier between the upper surface of the substrate and between a third insulator layer positioned between the upper surface of the substrate and between the charge retainer and to cause multiple charged particles of the electro-hole pairs to tunnel through the third insulator region.

6. The method according to claim 1 wherein the illuminating comprises illuminating the non-volatile memory cell with photons that have photon energy that is higher than a band-gap energy of the substrate.

7. The method according to claim 1 wherein the illuminating comprises illuminating the non-volatile memory cell with photons that have photon energy that is smaller than a sum of the band-gap energy of the substrate and the potential barrier between the substrate and between a third insulator layer positioned between the substrate and between the charge retainer.

8. The method according to claim 1 wherein the illuminating comprises illuminating the non-volatile memory cell with photons that have photon energy that is higher than a band-gap energy of the substrate and smaller than a sum of the band-gap energy of the substrate and a potential barrier between the substrate and between a third insulator layer positioned between the substrate and between the charge retainer.

9. The method according to claim 1 further comprising defining a required state of the non-volatile memory cell and selectively repeating the stages of illuminating and applying until the memory cell is at the required state.

10. The method according to claim 1 further comprising defining a required state of the non volatile memory cell; and setting an initial intensity of the light according to the required state.

11. The method according to claim 1 further comprising altering an intensity of the light between two iterations of the illuminating.

12. The method according to claim 1 further comprising illuminating a first non-volatile memory cell and a second non-volatile memory cell that is adjacent to the first memory cell and wherein the method further comprises applying at least one control voltage to at least one terminal of the second non-volatile memory cell such as to substantially prevent charged particles created in the substrate to be injected into a charge retainer of the second non-volatile memory cell.

13. The method according to claim 1 further comprising illuminating a first and second group of non-volatile memory cells, altering a state of a first group of non-volatile memory cells while preventing non-volatile memory cells of the second group from altering their state.

14. The method according to claim 1 wherein the illuminating comprises illuminating a non-volatile cell in which the charge retainer is a floating gate.

15. The method according to claim 1 wherein the illuminating comprises illuminating a non-volatile cell in which the charge retainer is a charge trapping region.

16. The method according to claim 1 wherein the illuminating comprises illuminating the substrate by diffractive illumination.

17. The method according to claim 16 wherein the illuminating comprises directing at least one light beam towards multiple light absorptive portions of multiple non-volatile memory cells positioned above multiple semiconductor regions of the multiple non-volatile memory cells.

18. The method according to claim 1 wherein the illuminating comprises illuminating the non-volatile memory cells by a light source positioned substantially above the non-volatile memory call and positioned substantially in parallel to the non-volatile memory cell.

19. A device comprising a non-volatile memory cell, wherein the non-volatile memory cell comprises: a light source, multiple terminals, and a charge retainer surrounded by an insulator; wherein the light source is adapted to illuminate the substrate; wherein the substrate comprises a first portion positioned deep within the substrate and a second portion located near an upper surface of the substrate; and wherein the non-volatile memory cell is adapted, in response to the illumination of the substrate and in response to an appliance of at least one control voltage to at least one terminal out of the multiple terminals, to cause charged particles out of electron-hole pairs created in the first portion and in the second portion to propagate towards the upper surface of the substrate and to be injected into the charge retainer.

20. The device according to claim 19 wherein the non-volatile memory cell is adapted to allow charged particles out of the electron-hole pairs to tunnel through a third insulator region positioned between the substrate and between the charge retainer.

21. The device according to claim 19 wherein the non-volatile memory cell is adapted to allow charged particles of the electron-hole pairs to accelerate towards the upper surface of the substrate and to surmount a potential barrier between the substrate and between a third insulator layer positioned between the substrate and between the charge retainer.

22. The device according to claim 19 wherein the non-volatile memory cell is adapted to allow multiple charged particle of the electron-hole pairs to surmount a potential barrier between the substrate and between a third insulator layer positioned between the substrate and between the charge retainer and also allow multiple charged particles of the electron-hole pairs to tunnel through the third insulator layer.

23. The device according to claim 19 wherein the light source is adapted to illuminate the non-volatile memory cell with photons that have photon energy that is higher than a band-gap energy of the substrate.

24. The device according to claim 19 wherein the light source is adapted to illuminate the non-volatile memory cell with photons that have photon energy that is smaller than a sum of a band-gap energy of the substrate and a potential barrier between the substrate and between a third insulator layer positioned between the substrate and between the charge retainer.

25. The device according to claim 19 wherein the light source is adapted to illuminate the non-volatile memory cell with photons that have photon energy that is higher than a band-gap energy of the substrate and is smaller than a sum of a band-gap energy of the substrate and a potential barrier between the substrate and between a third insulator layer positioned between the substrate and between the charge retainer.

26. The device according to claim 19 further adapted to adjust an intensity of light generated by the light source.

27. The device according to claim 19 wherein the light source is adapted to illuminate a first non-volatile memory cell and a second non-volatile memory cell that is adjacent to the first memory cell and wherein the device is adapted to applying at least one control voltage to at least one terminal of the second non-volatile memory cell such as to substantially prevent electrons created in the substrate to be injected into a charge retainer of the second non-volatile memory cell.

28. The device according to claim 19 wherein the device comprises a first group of non-volatile cells and a second group of non-volatile cells; wherein the device is adapted to simultaneously illuminate the first group and the second group of non-volatile memory cells, allow non-volatile memory cells that belong to the first group to alter their state while prevent non-volatile memory cells of the second group from altering their state.

29. The device according to claim 19 wherein the charge retainer is a floating gate.

30. The device according to claim 19 wherein the charge retainer is a charge trapping region.

31. The device according to claim 19 wherein the light source illuminates the substrate by diffractive illumination.

32. The device according to claim 31 wherein the light source is adapted to illuminate multiple non-volatile memory cells of the device by directing at least one light beam towards multiple light absorptive portions of multiple non-volatile memory cells positioned above multiple bodies of the multiple non-volatile memory cells.

33. The device according to claim 19 wherein the light source is positioned substantially in parallel to the non-volatile memory cell.

34. A device that comprises:
a first layer that comprises light absorptive control lines adapted to provide control signals to multiple non-volatile memory cells;
a second layer that comprises light absorptive control lines adapted to provide control signals to multiple non-volatile memory cells;
a third layer that comprises multiple charge retainers that are surrounded by an insulator; wherein the third layer is placed below the first and second layers; and a light source;
wherein each non-volatile memory cell further comprises a substrate that comprises multiple semiconductor pn junctions defined between a body and other semiconductor regions of the non-volatile memory cell;
wherein the substrate is placed below the third layer;
wherein the device is adapted to alter its state by a propagation of photo-generated charged particles between the substrate and between the charge retainer;
wherein the alteration of the state of the non-volatile memory cells is responsive to (i) a diffractive propagation of light through the first and second layers towards the substrate and (ii) a provision of control voltages to at least one light absorptive control line, wherein the diffractive propagation of light and the provision of at least one control voltage forces photo-generated charged particles to propagate between the substrate and between the charge retainer.

35. The device according to claim 34 wherein the device is adapted to alter its state while a reverse bias is maintained across at least one semiconductor pn junction within the substrate.

36. The device according to claim 34 wherein the device comprises a pair of semiconductor regions that form a semiconductor pn junction and wherein at least one semiconductor region of the pair is kept floating during the diffractive illumination.

37. The device according to claim 34 wherein the multiple non-volatile memory cells are arranged in a NAND format.

38. The device according to claim 34 wherein the multiple non-volatile memory cells are arranged in a NOR format.

39. The device according to claim 34 wherein the device is adapted to allow photo-generated charged particles to tunnel through an insulator positioned between the substrate and between the charge retainers.

40. The device according to claim 34 wherein the device is adapted to allow photo-generated charged particles to accelerate towards the upper surface of the substrate and to surmount a potential barrier between the substrate and between an insulator positioned between the substrate and between the charge retainers.

41. The device according to claim 34 wherein the device is adapted to allow multiple charged particle of the electron-hole pairs to surmount a potential barrier between the substrate and between an insulator positioned between the substrate and between the charge retainers and also allow multiple photo-generated charged particles to tunnel through the insulator.

42. The device according to claim 34 wherein the light source is adapted to illuminate the non-volatile memory cell with photons that have photon energy that is higher than band-gap energy of the substrate.

43. The device according to claim 34 wherein the light source is adapted to illuminate the non-volatile memory cell with photons that have photon energy that is smaller than a sum of a band-gap energy of the substrate and a potential barrier between the substrate and between an insulator positioned between the substrate and between the charge retainers.

44. The device according to claim 34 wherein the light source is adapted to illuminate the non-volatile memory cell with photons that have photon energy that is higher than a band-gap energy of the substrate and is smaller than a sum of a band-gap energy of the substrate and a potential barrier between the substrate and between an insulator positioned between the substrate and between the charge retainers.

45. The device according to claim 34 further adapted to adjust an intensity of light generated by the light source.

46. The device according to claim 34 wherein the light source is adapted to illuminate a first non-volatile memory cell and a second non-volatile memory cell that is adjacent to the first memory cell and wherein the device is adapted to applying at least one control voltage to at least one terminal of the second non-volatile memory cell such as to substantially prevent photo-generated electrons created in the substrate to be injected into a charge retainer of the second non-volatile memory cell.

47. The device according to claim 34 wherein the device comprises a first group of non-volatile memory cells and a second group of non-volatile memory cells; wherein the device is adapted to simultaneously illuminate the first group and the second group of non-volatile memory cells, allow non-volatile memory cells that belong to the first group to alter their state while prevent non-volatile memory cells of the second group from altering their state.

48. A method for altering a state of non-volatile memory cells, the method includes:
illuminating, by diffractive illumination, a substrate of a non-volatile memory cell, wherein the illuminating comprises diffractive propagation of light through a first layer, a second layer and a third layer of a device, wherein the first layer comprises light absorptive control lines adapted to provide control signals to multiple non-volatile memory cells, the second layer comprises light absorptive control lines adapted to provide control signals to multiple non-volatile memory cells, the third layer comprises multiple charge retainers that are surrounded by an insulator; wherein the third layer is placed below the first and second layers; and a light source; wherein the substrate comprises multiple semiconductor pn junctions defined between a body and other semiconductor regions of the non-volatile memory cell; wherein the substrate is placed below the first, second and third layers; and
providing at least one control voltage to at least one terminal of the non-volatile memory cell such as to alter a state of the non-volatile memory cell by propagation of photo-generated charged particles from the substrate to the charge retainer.

49. The method according to claim 48 wherein the providing comprises maintaining a reverse bias across at least one semiconductor pn junction within the substrate.

50. The method according to claim 48 wherein the providing comprises maintaining at least one semiconductor region out of a pair of semiconductor regions that form a semiconductor pn junction floating.

51. The method according to claim 48 wherein the illuminating comprises illuminating multiple non-volatile memory cells that are arranged in a NAND format.

52. The method according to claim 48 wherein the illuminating comprises illuminating multiple non-volatile memory cells that are arranged in a NOR format.

53. The method according to claim 48 wherein the illuminating and providing cause photo-generated charged particles to tunnel through an insulator positioned between the substrate and between the charge retainers.

54. The method according to claim 48 wherein the illuminating and providing cause photo-generated charged particles to accelerate towards the upper surface of the substrate and surmount a potential barrier between an upper surface of the substrate and between an insulator positioned between the upper surface of the substrate and between the charge retainer.

55. The method according to claim 48 wherein the illuminating and providing cause photo-generated charged particles to surmount a potential barrier between an upper surface of the substrate and between an insulator positioned between the upper surface of the substrate and between the charge retainers and to cause multiple photo-generated charged particles to tunnel through the insulator.

56. The method according to claim 48 wherein the illuminating comprises illuminating the non-volatile memory cell with photons that have photon energy that is higher than a band-gap energy of the substrate.

57. The method according to claim 48 wherein the illuminating comprises illuminating the non-volatile memory cell with photons that have photon energy that is smaller than a sum of the band-gap energy of the substrate and the potential barrier between the substrate and between an insulator positioned between the substrate and between the charge retainers.

58. The method according to claim 48 wherein the illuminating comprises illuminating the non-volatile memory cell with photons that have photon energy that is higher than a band-gap energy of the substrate and smaller than a sum of the band-gap energy of the substrate and a potential barrier between the substrate and between an insulator positioned between the substrate and between the charge retainers.

59. The method according to claim 48 further comprising defining a required state of a non-volatile memory cell and selectively repeating the stages of illuminating and providing until the non-volatile memory cell is at the required state.

60. The method according to claim 48 further comprising defining a required state of a non volatile memory cell and setting an initial intensity of the light according to the required state.

61. The method according to claim 48 further comprising altering an intensity of the light between two iterations of the illuminating.

62. The method according to claim 48 further comprising illuminating a first non-volatile memory cell and a second non-volatile memory cell that is adjacent to the first memory cell and wherein the method further comprises applying at least one control voltage to at least one terminal of the second non-volatile memory cell such as to substantially prevent photo-generated charged particles created in the substrate to be injected into a charge retainer of the second non-volatile memory cell.

63. The method according to claim 48 further comprising illuminating a first and second group of non-volatile memory cells, altering a state of a first group of non-volatile memory cells while preventing non-volatile memory cells of the second group from altering their state.
